(19) United States
(12) Patent Application Publication
(10) Pub. No.: US 2018/0338386 A1
(43) Pub. Date: Nov. 22, 2018

(54) HEAT DISSIPATING STRUCTURE FOR POWER SUPPLY AND HEAT DISSIPATING METHOD THEREOF

(71) Applicant: LIEN CHANG ELECTRONIC ENTERPRISE CO., LTD., TAIPEI CITY (TW)

(72) Inventor: CHIEN-TA CHEN, TAOYUAN CITY (TW)

(21) Appl. No.: 15/596,991

(22) Filed: May 16, 2017

(51) Int. Cl. H05K 7/20; H05K 1/02; H05K 1/18

(52) U.S. Cl. CPC H05K 7/209; H05K 1/181; H05K 1/0204; H05K 7/20472

(57) ABSTRACT

A heat dissipating structure for a power supply is provided. The power supply includes a casing and a circuit module disposed in the casing. The heat dissipating structure includes at least one heat dissipating sheet, an inner material layer and an outer material layer, and a power device. The heat dissipating sheet is embedded in the casing through an insert molding process. The inner material layer and an outer material layer are formed on the inner surface and outer surface of the heat dissipating sheet respectively. The power device is disposed on the circuit board substrate. A hole portion corresponding to the contact member is disposed in the inner material layer such that the power device contacts the heat dissipating sheet through the hole portion.

### BACKGROUND OF THE INVENTION

### 1. Field of the Invention

The present disclosure relates to a heat dissipating structure for a power supply and a heat dissipating method thereof; more particularly, to a heat dissipating structure for an external power supply.

### 2. Description of Related Art

Most laptop computers or electronic mobile devices use external power supply. However, when being used, an external power supply can cause electromagnetic interference and the circuit components therein often have a high temperature. Therefore, the reduction of electromagnetic interference and heat dissipation are important considerations in the design of an external power supply.

FIGS. 1 and 2 show a conventional external power supply, which includes a shell 1, a circuit module 2 disposed in the shell 1, an insulating sheet 3 encircling the circuit module 2, and a metal isolating sheet 4.

With reference to FIG. 2, after the power supply is assembled, the metal isolating sheet 4 encloses the outer side of the circuit module 2, and the gap between the metal isolating sheet 4 and the shell 1 is filled with an adhesive 5 so that the metal isolating sheet 4 and the shell 1 stick to each other. The heat generated by the circuit components of the circuit module 2 can be transmitted to the metal isolating sheet 4 and then to the shell 1 through the adhesive 5, and finally dissipate into the air. In this way, the circuit module 2 can be cooled down. Furthermore, a connecting portion 6 is disposed at one end of the metal isolating sheet 4 and connected to a circuit board substrate of the circuit module 2 such that a ground terminal of the circuit module 2 is electrically connected to the metal isolating sheet 4, by which the metal isolating sheet 4 can shield and suppress electromagnetic waves.

In the conventional heat dissipating structure described above, the circuit module 2 and the metal isolating sheet 4 need to be separated by an isolating sheet 3, which lengthens the heat conduction path and lowers the heat dissipation efficiency. In addition, in an assembly process of a conventional power supply, the circuit module 2 is covered by the insulating sheet 3 and the metal isolating sheet 4 in sequence, and the adhesive 5 is applied to the outer surface of the metal isolating sheet 4. Afterwards, the circuit module 2, the insulating sheet 3, and the metal isolating sheet 4 are altogether disposed in the shell 1. Therefore, the above described assembly process is complicated and time-consuming.

For the above described reasons, a power supply using a conventional heat dissipation structure has a poor heat dissipation efficiency and high assembly costs. Accordingly, to provide a structural solution in order to overcome the abovementioned shortcomings has become an important issue in the art.

### SUMMARY OF THE INVENTION

In order to achieve the aforementioned objects, the present disclosure provides a heat dissipating structure for a power supply, in which the power supply includes a casing and a circuit module disposed in the casing, and the circuit module includes a circuit board substrate. The heat dissipation structure includes at least one heat dissipating sheet, an inner material layer and an outer material layer included in the casing, and a power device disposed on the circuit board substrate. The at least one heat dissipating sheet is disposed in the casing through an insert molding process. The heat dissipating sheet includes at least one flat portion and two side portions respectively connected to the at least one flat portion. At least one of the flat portion and the two side portions are close to the circuit board substrate and parallel thereto. The inner material layer is formed on a lateral surface of the at least one heat dissipating sheet facing the circuit module, and the outer material layer is formed on another lateral surface of the at least one heat dissipating sheet facing a direction away from the circuit module. The at least one heat dissipating sheet is located between the outer material layer and the inner material layer, and the inner material layer is located between the at least one heat dissipating sheet and the circuit module. A hole portion corresponding to the power device is disposed in the inner material layer in a manner such that the at least one heat dissipating sheet is exposed from the inner material layer at the hole portion and the power device directly or indirectly contacts the at least one heat dissipating sheet via the hole portion so that the heat generated by the power device is transmitted to the at least one heat dissipating sheet.

According to one embodiment of the present disclosure, the power device is a power chip, and a thermally conductive member is disposed between the power device and a portion of the at least one heat dissipating sheet that is exposed at the hole portion.

According to one embodiment of the present disclosure, a contact member is disposed on the circuit board substrate, in which an end of the contact member is electrically connected with a ground terminal, and another end of the contact member is electrically connected with the at least one heat dissipating sheet.

According to one embodiment of the present disclosure, the contact member is a metal rod, and an insertion member is disposed on a portion of the at least one heat dissipating sheet that corresponds to the contact member. The insertion member is electrically connected to the at least one heat dissipating sheet and has an insertion hole corresponding to the contact member and a plurality of slits disposed around the insertion hole. The diameter of the insertion hole is equal to or greater than that of the contact member so that the contact member can be electrically connected to the at least one heat dissipating sheet through the insertion member.

According to one embodiment of the present disclosure, the contact member is selected from a group of electrically conductive components consisting of: a conductive elastic sheet, a conductive spring, a conductive wire, and a conductive sponge.

Another embodiment of the present disclosure provides a heat dissipating method for a power supply, in which the power supply includes a casing and a circuit module disposed in the casing, and the circuit module includes a circuit board substrate. The heat dissipating method includes: disposing a heat dissipating sheet in the casing through an insert molding process, the heat dissipating sheet having at least one flat portion and two side portions respectively connected to the at least one flat portion, at least one of the flat portion and the two side portions being close to the circuit board substrate and parallel thereto; forming an inner material layer on a lateral surface of the heat dissipating sheet facing the circuit module and an outer material layer on another lateral surface of the heat dissipating sheet facing a direction away from the circuit module, the inner material layer and the outer material layer being included in the casing, in which the heat dissipating sheet is located between the outer material layer and the inner material layer, and the inner material layer is located between the heat dissipating sheet and the circuit module; and disposing a power device on the circuit board substrate and a hole portion in the inner material layer, in which the hole portion corresponds to the power device in a manner such that the heat dissipating sheet is exposed from the inner material layer at the hole portion and the power device directly or indirectly contacts the heat dissipating sheet via the hole portion, so that the heat generated by the power device is transmitted to the heat dissipating sheet.

The present disclosure is advantageous in that the heat dissipating structure can enhance the heat dissipation efficiency of a power supply and simplify the assembly process thereof, thereby reducing the associated costs.

In order to further the understanding of the present disclosure, the following embodiments are provided along with illustrations to facilitate the disclosure of the present disclosure.

### BRIEF DESCRIPTION OF THE DRAWINGS

FIG. 1 is a perspective exploded view illustrating a conventional power supply heat dissipating structure.

FIG. 2 is a sectional view illustrating the conventional power supply heat dissipating structure.

FIG. 3 is a perspective exploded view illustrating a heat dissipating structure for a power supply according to a first embodiment of the present disclosure.

FIG. 4 is a sectional exploded view illustrating the heat dissipating structure according to the first embodiment of the present disclosure.

FIG. 4A is a fragmentary sectional view illustrating the heat dissipating structure according to the first embodiment of the present disclosure.

FIG. 5 is a sectional view illustrating the heat dissipating structure according to the first embodiment of the present disclosure.

FIG. 6 is a sectional view illustrating the heat dissipating structure according to a second embodiment of the present disclosure.

FIG. 7 is a sectional view illustrating the heat dissipating structure according to a third embodiment of the present disclosure.

FIG. 8 is sectional view illustrating the heat dissipating structure according to a fourth embodiment of the present disclosure.

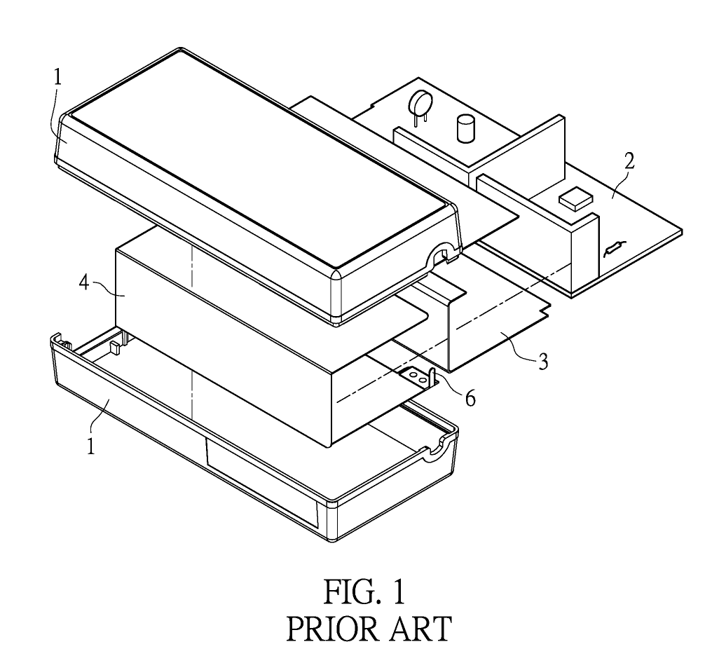

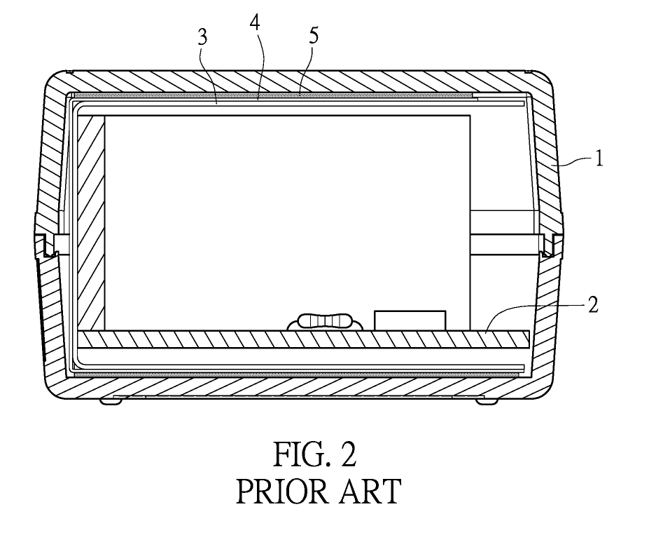

### DETAILED DESCRIPTION OF THE PREFERRED EMBODIMENTS

The aforementioned illustrations and following detailed description are exemplary for the purpose of further explaining the scope of the present disclosure. Other objectives and advantages related to the present disclosure will be illustrated in the following description and appended drawings.

### First Embodiment

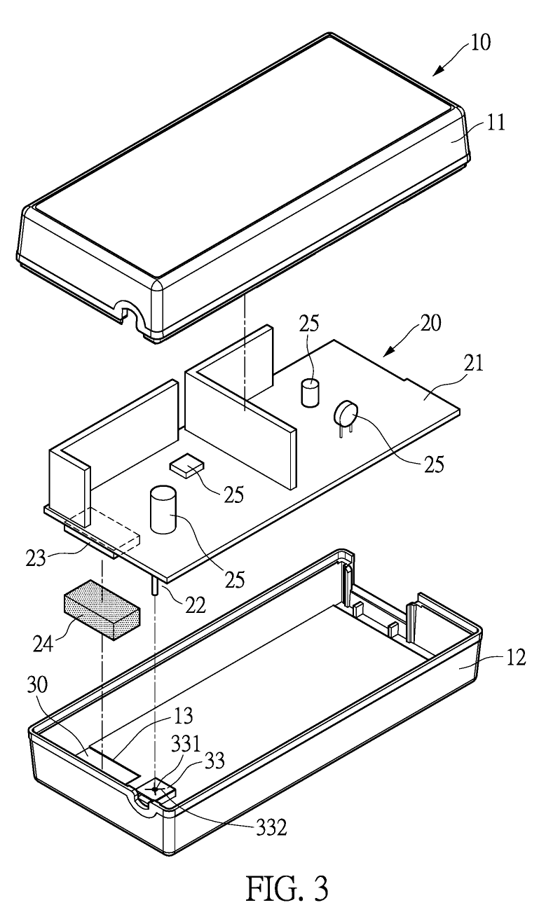

With reference to FIGS. 3 to 5, the power supply to which the heat dissipating structure is applied includes a casing 10, a circuit module 20, and a heat dissipating sheet 30. The circuit module 20 is disposed in the casing 10, and the heat dissipating sheet 30 is embedded in the casing 10 and encloses the circuit module 20.

The casing 10 is made of plastic and formed through an injection molding process. The casing 10 includes an accommodating space that accommodates the circuit module 20. The circuit module 20 includes a circuit board substrate 21, on which a plurality of circuit components 25 are disposed. The circuit components 25 form circuits such as a rectification circuit and a transformer circuit. The heat dissipating sheet 30 is made of materials with high thermal conductivity and electrical conductivity, such as a metal plate. The heat dissipating sheet 30 is embedded in the casing 10 through an insert molding process. The heat dissipating sheet 30 includes a flat portion 31 and two side portions 32 respectively connected to both sides of the flat portion 31. At least one of the flat portion 31 and the two side portions 32 are close to the circuit board substrate and parallel thereto so that the heat generated by the circuit module 20 can be transmitted to the heat dissipating sheet 30, enhancing the heat dissipation efficiency of the circuit module 20 and suppressing electromagnetic interference caused by the circuit module 20.

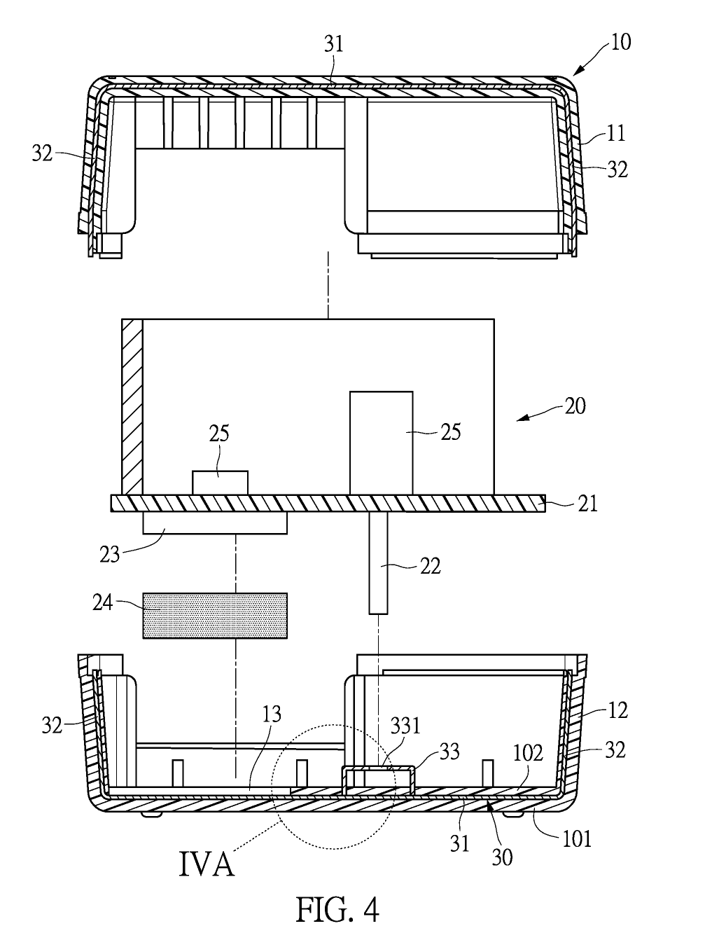

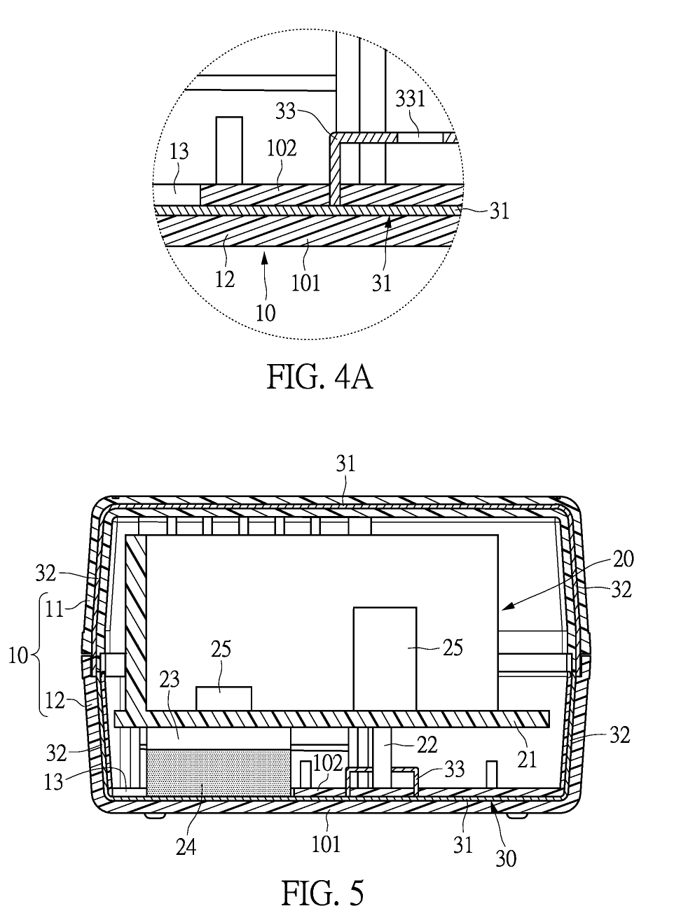

In the first embodiment of the heat dissipating structure for a power supply, the casing 10 includes a top casing 11 and a bottom casing 12. After the top casing 11 and the bottom casing 12 are assembled together, an accommodating space inside the casing 10, which is used for accommodating the circuit module 20, is formed. The top casing 11 and the bottom casing 12 of the casing 10 are made of plastic and formed through an injection molding process, and the heat dissipating sheet 30 is disposed into the injection mold during the injection molding process such that the heat dissipating sheet 30 is embedded into the top casing 11 and the bottom casing 12. Referring to FIG. 4A, an inner material layer 102 is formed on a lateral surface of the heat dissipating sheet 30 facing the circuit module 20, and an outer material layer 101 is formed on another lateral surface of the heat dissipating sheet 30 facing a direction away from the circuit module 20. The outer material layer 101 and the inner material layer 102 are included in the casing 10. Accordingly, a sandwich structure in which the heat dissipating sheet 30 is interposed between the outer material layer 101 and the inner material layer 102 is formed.

With reference to FIGS. 4 and 5, after the top casing 11 and the bottom casing 12 are assembled together, a lateral surface of the heat dissipating sheet 30 facing the circuit module 20 is covered by the inner material layer 102 so that the heat dissipating sheet 30 is insulated from the circuit module 20 by the inner material layer 102. In this way, the present disclosure obviates the need for an extra insulating sheet.

Referring to FIGS. 4 and 5, in the first embodiment, the top casing 11 and the bottom casing 12 each include a heat dissipating sheet 30 embedded therein, in which the flat portion 31 of each of the heat dissipating sheets 30 is located at the upper side of the top casing 11 and the bottom side of the bottom casing 12 respectively. The two side portions 32 of each of the heat dissipating sheets 30 are respectively located at the two laterals sides of the top casing 11 and that of the bottom casing 12.

Accordingly, with reference to FIG. 5, when the top casing 11 and the bottom casing 12 are assembled together, the circuit module 20 is enclosed within the inner surfaces of the top casing 11 and the bottom casing 12. Furthermore, the flat portion 31 of each of the heat dissipating sheets 30 is located at the upper side and the bottom side of the circuit module 20 respectively, and the two side portions 32 of each of the heat dissipating sheets 30 are at both sides of the circuit module 20, thereby enclosing the circuit module 20 on four sides.

Referring to FIG. 5, the heat generated by the circuit module 20 can be transmitted to the heat dissipating sheet 30 through the inner material layer 102 of the casing 10, and then to the outer material layer 101, and further to the casing 10 and finally dissipate into the air. Since the heat dissipating sheet 30 is made of a thermally conductive material, the heat generated by the circuit components 25 of the circuit module 20 can be transmitted to the whole heat dissipating sheet 30. In this way, the dissipation area as well as the heat dissipation efficiency of the circuit module 20 are increased.

Furthermore, with reference to FIGS. 3, 4A, and 5, a power device 23 is disposed on the circuit board substrate 21 of the circuit module 20. In general, when in operation, thermal energy in a power supply is mostly generated by the power device 23, thus making the power device 23 the part of the circuit module 20 with the highest temperature. Therefore, in the present disclosure, a hole portion 13 is disposed in the inner material layer 102, in which the hole portion 13 corresponds to the power device 23 such that the heat dissipating sheet 30 can be exposed from the inner material layer 102 at the hole portion 13 and the power device 23 can directly or indirectly contact the heat dissipating sheet 30 through the hole portion 13. In this way, the heat generated by the power device 23 can be transmitted to the heat dissipating sheet 30 without being blocked by the casing 10, and therefore the heat dissipation efficiency of the circuit module 20 is enhanced. In this embodiment, the power device 23 contacts the heat dissipating sheet 30 through a thermally conductive member 24. The thermally conductive member 24 can be a thermally conductive pad or a thermal gap filler. The thermally conductive member 24 has a high thermal conductivity so that the heat transmitted from the heat dissipating sheet 30 can be further transmitted to the heat dissipating sheet 30 rapidly.

Besides being able to dissipate heat, the heat dissipating sheet 30 can also shield electromagnetic waves and suppress electromagnetic interference caused by the circuit module 20. With reference to FIGS. 3 and 5, the circuit board substrate 21 includes a ground terminal (not shown in the drawings), and a contact member 22 is disposed on the circuit board substrate 21, in which one end of the contact member 22 is electrically connected to the ground terminal, and another end of the contact member 22 is electrically connected with the heat dissipating sheet 30. With the contact member 22 being connected to the heat dissipating sheet 30, the ground terminal of the circuit board substrate 21 can be electrically connected to the heat dissipating sheet 30.

In the present embodiment, the contact member 22 is a metal rod, and an insertion member 33 is disposed on a portion of the heat dissipating sheet 30 that corresponds to the contact member 22. In the present embodiment, the insertion member 33 is roughly rectangular, and has an insertion hole 331 corresponding to the contact member 22 and a plurality of slits 332 disposed around the insertion hole 331 so that the diameter of the insertion hole 331 can be expanded. The insertion member 33 is welded on the heat dissipating sheet 30 and protrudes from the inner material layer 102. The center of the insertion hole 331 corresponds to the contact member 22 of the circuit module 20, and the diameter of the insertion hole 331 is equal to or greater than that of the contact member 22 so that after the heat dissipating structure is assembled, the contact member 22 can be electrically connected to the heat dissipating sheet 30 through the insertion hole 331 such that the ground terminal of the circuit board substrate 21 can be electrically connected to the heat dissipating sheet 30.

It should be noted that the structure of the contact member 22 is not limited to the above-described. Any other technical means that allows the ground terminal of the circuit module 20 to be in electrical connection with the heat dissipating sheet 30 can be applied to the present disclosure. For example, with reference to FIG. 8, the contact member 22a is a conductive elastic sheet. The contact member 22 can also be other electrically conductive components such as a conductive spring, a conductive wire, or a conductive sponge.

With reference to FIG. 5, in the first embodiment, the ends of the two side portions 32 of each of the heat dissipating sheets 30 are exposed from the ends of the two lateral sides of the top casing 11 and the bottom casing 12. Therefore, when the top casing 11 and the bottom casing 12 are assembled together, the two side portions 32 of the heat dissipating sheet 30 embedded in the top casing 11 can be electrically connected to the two side portions 32 of the heat dissipating sheet 30 embedded in the bottom casing 12. In this way, a conductive body enclosing the circuit module 20 can be formed, and the electromagnetic waves generated by the circuit module 20 can be suppressed more effectively.

Compared to a conventional heat dissipating structure, the heat dissipating structure of the present disclosure is characterized in that the heat dissipating sheet 30 is embedded inside the casing 10 through an insert molding process and is therefore integrated into the casing 10, thereby reducing the number of components. Furthermore, the inner material layer 102 is disposed between the inner side of the heat dissipating sheet 30 and the circuit module 20, insulating the heat dissipating sheet 30 from the circuit module 20. Therefore, the present disclosure dispenses with the need for an extra insulating sheet. Hence, the assembly process of a power supply using the heat dissipating structure of the present disclosure is simplified; the assembly process can be completed by simply joining the top casing 11 and the bottom casing 12 together. Compared to the assembly process of a power supply using a conventional heat dissipating structure, the assembly process of a power supply using the heat dissipating structure of the present disclosure obviates the steps of covering a circuit module with an insulating sheet and a heat dissipating sheet, and applying an adhesive to the outer side of the heat dissipating sheet and the attaching the heat dissipating sheet to the inner surface of the casing. Hence, the present disclosure simplifies the assembly process of a power supply and lowers the production costs.

Moreover, by embedding the heat dissipating sheet 30 into the casing 10, an insulating sheet for insulating the heat dissipating sheet 30 from the circuit module 20 and the adhesive joining the heat dissipating sheet 30 with the casing 10 can both be dispensed with. In this manner, the heat conduction path of the circuit module 20 is shortened, and the heat dissipation efficiency is thus increased.

### Second Embodiment

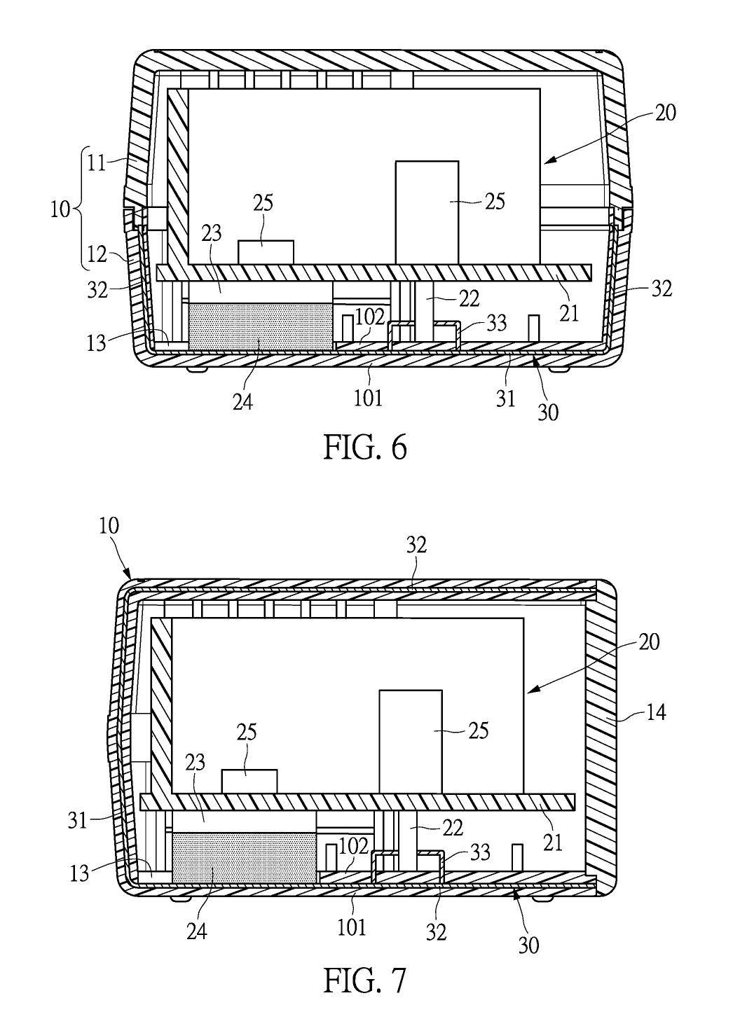

With reference to FIG. 6, in the second embodiment of the present disclosure, the casing 10 is formed of, as in the first embodiment, a top casing 11 and a bottom casing 12; however, in the present embodiment, only the bottom casing 12 includes a heat dissipating sheet 30 therein, i.e. the top casing 11 does not include a heat dissipating sheet 30. In the present embodiment, the flat portion 31 of the heat dissipating sheet 30 is embedded in the bottom side of the bottom casing 12, and the two side portions 32 are embedded in the two lateral sides of the bottom casing 12 respectively. Accordingly, after the casing 10 and the circuit module 20 are assembled together, the bottom surface of the circuit board substrate 21 is adjacent to the flat portion 31 of the heat dissipating sheet 30 and parallel thereto.

In the second embodiment, the flat portion 31 and the two side portions 32 are interposed between the outer material layer 101 and the inner material layer 102 of the casing 10, and a hole portion 13 corresponding to the power device 23 is disposed in the inner material layer 102 such that the heat dissipating sheet 30 is exposed from the inner material layer 102 at the hole portion 13 and the power device 23 can directly contact the heat dissipating sheet 30 or indirectly contact the heat dissipating sheet 30 through a thermally conductive member 24, such that the heat generated by the power device 23 can be transmitted to the heat dissipating sheet 30.

### Third Embodiment

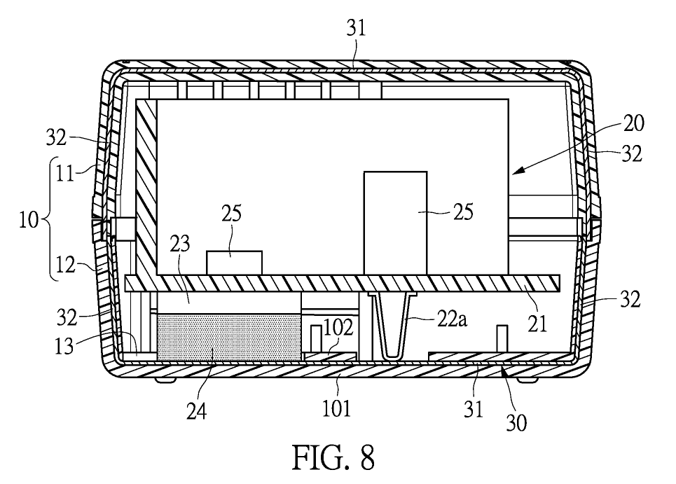

Referring to FIG. 7, in the third embodiment of the present disclosure, the casing 10 is U-shaped and has an opening. A lid 14 is disposed at the opening. The casing 10 and the lid 14 form a shell enclosing the circuit module 20 after the lid 14 covers the opening. In the present embodiment, the heat dissipating sheet 30 is formed inside the casing 10 through an insert molding process, in which the flat portion 31 of the heat dissipating sheet 30 is embedded in the lateral side of the casing 10 and the two side portions 32 of the heat dissipating sheet 30 are embedded in the top side and the bottom side of the casing 10 respectively so that the flat portion 31 of the heat dissipating sheet 30 encloses the circuit module 20 on a lateral side thereof, and the two side portions 32 of the heat dissipating sheet 30 enclose the circuit module 20 on the top side and the bottom side thereof.

In the present embodiment, the heat dissipating sheet 30 is interposed between the outer material layer 101 and the inner material layer 102 of the casing 10, and a hole portion 13 corresponding to the power device 23 is disposed in the inner material layer 102 such that the heat dissipating sheet 30 is exposed from the inner material layer 102 at the hole portion 13 and the power device 23 can contact the heat dissipating sheet 30 through the thermally conductive member 24.

In summary, the heat dissipating sheet 30 of the present disclosure is made of plastic and formed in the casing 10 through an insert molding process, through which the present disclosure obviates the need for an insulating sheet insulating the heat dissipating sheet 30 from the circuit module 20, thereby enhancing the heat dissipation efficiency of the power supply. Furthermore, the assembly process of the power supply is simplified, dispensing with the steps of assembling an isolating sheet and a heat dissipating sheet with the circuit module and applying an adhesive to the outer surface of the heat dissipating sheet, thereby reducing the time for assembling the power supply and thus lowering the associated costs.

The description illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

1. A heat dissipating structure for a power supply, wherein the power supply includes a casing and a circuit module disposed in the casing, the circuit module including a circuit board substrate, the heat dissipation structure comprising:
at least one heat dissipating sheet embedded in the casing through an insert molding process, the at least one heat dissipating sheet including at least one flat portion and two side portions respectively connected to the at least one flat portion, at least one of the flat portion and the two side portions being close to the circuit board substrate and parallel thereto;
an inner material layer and an outer material layer included in the casing, the inner material layer being formed on a lateral surface of the at least one heat dissipating sheet facing the circuit module, the outer material layer being formed on another lateral surface of the at least one heat dissipating sheet facing a direction away from the circuit module, wherein the at least one heat dissipating sheet is located between the outer material layer and the inner material layer, and the inner material layer is located between the at least one heat dissipating sheet and the circuit module;
a power device disposed on the circuit board substrate, wherein a hole portion corresponding to the power device is disposed in the inner material layer in a manner such that the at least one heat dissipating sheet is exposed from the inner material layer at the hole portion and the power device directly or indirectly contacts the at least one heat dissipating sheet via the hole portion so that the heat generated by the power device is transmitted to the at least one heat dissipating sheet
a contact member disposed on the circuit board substrate, wherein the contact member is a metal rod; and
an insertion member disposed on a portion of the at least one heat dissipating sheet that corresponds to the contact member, the insertion member being electrically connected to the at least one heat dissipating sheet and having an insertion hole corresponding to the contact member and a plurality of slits disposed around the insertion hole, wherein a diameter of the insertion hole is equal to or greater than that of the contact member so that the contact member can be electrically connected to the at least one heat dissipating sheet through the insertion member.

2. The heat dissipating structure according to claim 1, wherein a thermally conductive member is disposed between the power device and a portion of the at least one heat dissipating sheet that is exposed at the hole portion, the power device being a power chip, and the thermally conductive member being a thermally conductive pad or a thermal gap filler.

3. The heat dissipating structure according to claim 2, wherein one end of the contact member being electrically connected with a ground terminal, another end of the contact member being electrically connected with the at least one heat dissipating sheet.

4. (canceled)

5. The heat dissipating structure according to claim 3, wherein the contact member is selected from a group of electrically conductive components consisting of: a conductive elastic sheet, a conductive spring, a conductive wire, and a conductive sponge.

6. The heat dissipating structure according to claim 5, wherein the casing includes a top casing and a bottom casing, the at least one heat dissipating sheet being disposed in the bottom casing.

7. The heat dissipating structure according to claim 5, wherein the casing includes a top casing and a bottom casing, the top casing and the bottom casing each including one heat dissipating sheet disposed therein, and wherein the heat dissipating sheet in the top casing and that in the bottom casing are electrically connected to each other after the top casing and the bottom casing are assembled together.

8. A heat dissipating method for a power supply, wherein the power supply includes a casing and a circuit module disposed in the casing, the circuit module including a circuit board substrate, the heat dissipating method comprising:
embedding a heat dissipating sheet in the casing through an insert molding process, the heat dissipating sheet having at least one flat portion and two side portions respectively connected to the at least one flat portion, at least one of the flat portion and the two side portions being close to the circuit board substrate and parallel thereto;
forming an inner material layer on a lateral surface of the heat dissipating sheet facing the circuit module and an outer material layer on another lateral surface of the heat dissipating sheet facing a direction away from the circuit module, the inner material layer and the outer material layer being included in the casing, wherein the heat dissipating sheet is located between the outer material layer and the inner material layer, and the inner material layer is located between the heat dissipating sheet and the circuit module; and
disposing a power device on the circuit board substrate and a hole portion in the inner material layer, wherein the hole portion corresponds to the power device in a manner such that the heat dissipating sheet is exposed from the inner material layer at the hole portion and the power device directly or indirectly contacts the heat dissipating sheet via the hole portion so that the heat generated by the power device is transmitted to the heat dissipating sheet.

9. The heat dissipating method according to claim 8, wherein the circuit board substrate of the circuit module includes a ground terminal, and a contact member being disposed on the circuit board substrate, an end of the contact member being electrically connected to the circuit board substrate, and another end of the contact member being electrically connected to the heat dissipating sheet.

10. The heat dissipating method according to claim 8, wherein a thermally conductive member is disposed between the power device and a portion of the heat dissipating sheet that is exposed at the hole portion in a manner such that the heat generated by the power device is transmitted to the heat dissipating sheet.
